(19) United States
(12) Patent Application Publication
(10) Pub. No.: US 2013/0203233 A1
(43) Pub. Date: Aug. 8, 2013

(54) MANUFACTURING METHOD OF MEMORY CAPACITOR WITHOUT MOAT STRUCTURE

(71) Applicants: TZUNG-HAN LEE, TAIPEI CITY (TW); CHUNG-LIN HUANG, TAOYUAN COUNTY (TW); RON-FU CHU, TAIPEI CITY (TW)

(72) Inventors: TZUNG-HAN LEE, TAIPEI CITY (TW); CHUNG-LIN HUANG, TAOYUAN COUNTY (TW); RON-FU CHU, TAIPEI CITY (TW)

(73) Assignee: INOTERA MEMORIES, INC., TAOYUAN COUNTY (TW)

(21) Appl. No.: 13/461,921

(22) Filed: May 2, 2012

(30) Foreign Application Priority Data
Feb. 3, 2012 (TW) 101103499

(51) Int. Cl. H01L 21/02

(52) U.S. Cl. 438/386; 257/E21.011

(57) ABSTRACT

A manufacturing method of a memory capacitor without a moat structure includes the steps of: providing a semiconductor substrate defined with an array region and a peripheral region; forming a first oxidized layer on the array region; forming a second oxidized layer on the peripheral region; planarizing the first and the second oxidized layers; forming an insulating layer on the first and the second oxidized layers; forming a plurality of trenches on the array region, where the trenches pass through the first oxidized layer and the insulating layer on the first oxidized layer; forming a conductive layer on the side and base surfaces of each trench; removing a portion of the conductive layer and a portion of the insulating layer to form a plurality of notches to expose the first oxidized layer; and removing the first oxidized layers which are exposed from the notches.

### BACKGROUND OF THE INSTANT DISCLOSURE

1. Field of the Instant Disclosure

The instant disclosure relates to a manufacturing method of a random access memory capacitor; in particular, to a manufacturing method of a dynamic random access memory (DRAM) capacitor without a moat structure.

2. Description of Related Art

Along with the minimization of the electronic products, the components of the semiconductor are also improved to be designed smaller. Meanwhile, the manufacturing process of semiconductors is also advancing rapidly which enables the semiconductor chips to attain stronger functions for the electronic products, such as a higher density, a higher efficiency, and lower power consumption. Nevertheless, conventional memory devices usually include a transistor, a capacitor, and a peripheral control circuit. Therefore, in order to achieve a higher efficiency for the memory devices, finding a way for more capacitors to be arranged within the very limited area shall be able to achieve the required effect.

Please refer to FIG. 1, which shows a structure of a conventional memory capacitor. A semiconductor substrate 1 is defined with an array region A and a peripheral region P. A plurality of trenches 3 is formed on the array region A to divide an oxide layer 2, and each trench 3 is defined by at least one side surface and a base, and an insulating layer 4 is formed on the oxide layer 2. A conductive layer 5 is formed on the array region A, where the conductive layer 5 is formed particularly on the side surfaces and base of the trenches 3 and on the insulating layer 4. For the peripheral region P, the conductive layer 5 is formed on the insulating layer 4. The conductive layer 5 serves as an electrode for the capacitor. Furthermore, a moat 6 is formed between the array region A and the peripheral region P to separate the two. Since the oxide layers 2 of the array region A and the peripheral region P are made of the same material, the moat 6 is necessary to distinctly separate the two regions.

### SUMMARY OF THE INSTANT DISCLOSURE

The object of the instant disclosure is to provide a semiconductor structure without a moat structure to increase the amount of capacitors in the memory device. Specifically speaking, the area for disposing the capacitors is enlarged to accommodate more capacitors.

The instant disclosure provides a manufacturing method of a memory capacitor without a moat structure. The method comprises the following steps: providing a semiconductor substrate defined with an array region and a peripheral region; forming a first oxidized layer on the array region; forming a second oxidized layer on the peripheral region; planarizing the first and the second oxidized layers to form an insulating layer on the first and the second oxidized layers; forming a plurality of trenches on the array region, where the trenches penetrate the first oxidized layer and the insulating layer on the first oxidized layer; forming a conductive layer on the inner and base surfaces of each trench; removing a portion of the conductive layer and a portion of the insulating layer to form a plurality of notches exposing the first oxidized layer; removing the first oxidized layers which are exposed from the notches to complete the manufacturing process of the memory capacitor without a moat.

Based on the above, the semiconductor structure formed from the manufacturing method of the memory capacitor without a moat structure provided by the instant disclosure does not have the moat structure. Therefore, the area for accommodating the capacitors is increased. Furthermore, the instant disclosure is particularly useful for manufacturing the 4F2 DRAM with greater ease.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 shows a cross-sectional view of a conventional memory capacitor.

FIG. 2 is a schematic view showing the deposition of a first oxide layer according to a manufacturing method of the instant disclosure.

FIG. 3 is a schematic view showing the patterned first oxidized layer according to the manufacturing method of the instant disclosure.

FIG. 4 is a schematic view showing the formation of the first oxidized layer according to the manufacturing method of the instant disclosure.

FIG. 5 is a schematic view showing the deposition of a second oxidized layer according to the manufacturing method of the instant disclosure.

FIG. 6 is a schematic view showing the covering of a photoresistance layer on the second oxidized layer according to the manufacturing method of the instant disclosure.

FIG. 7 is a schematic view showing the patterned second oxidized layer according to the manufacturing method of the instant disclosure.

FIG. 8 is a schematic view showing the planarizing process according to the manufacturing method of the instant disclosure.

FIG. 9 is a schematic view showing the formation of an insulating layer according to the manufacturing method of the instant disclosure.

FIG. 10 is a schematic view of the formation of trenches according to the manufacturing method of the instant disclosure.

FIG. 11 is a schematic view of the formation of the conductive layer according to the manufacturing method of the instant disclosure.

FIG. 12 is a schematic view of the exposure of the first oxidized layer according to the manufacturing method of the instant disclosure.

FIG. 13 is a schematic view of the removal of the first oxidized layer from the notches according to the manufacturing method of the instant disclosure.

FIG. 14 shows a flow chart of the manufacturing method of the instant disclosure.

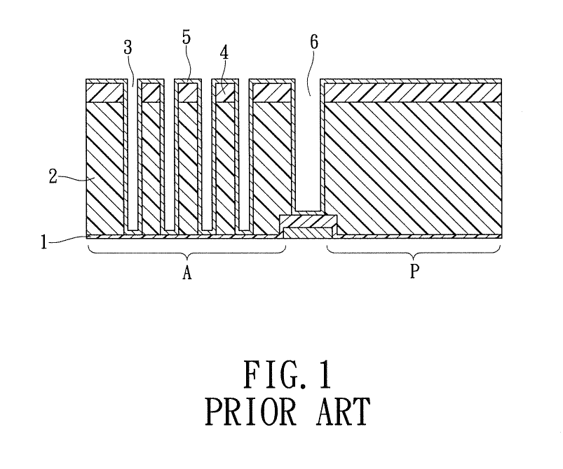

### DETAILED DESCRIPTION OF THE PREFERRED EMBODIMENTS

A manufacturing method of a memory capacitor without a moat structure is provided in the instant disclosure. The method includes the following steps:

Providing a semiconductor substrate 10 defined with an array region A and a peripheral region P thereon, where the peripheral region P is arranged around the periphery of the array region A.

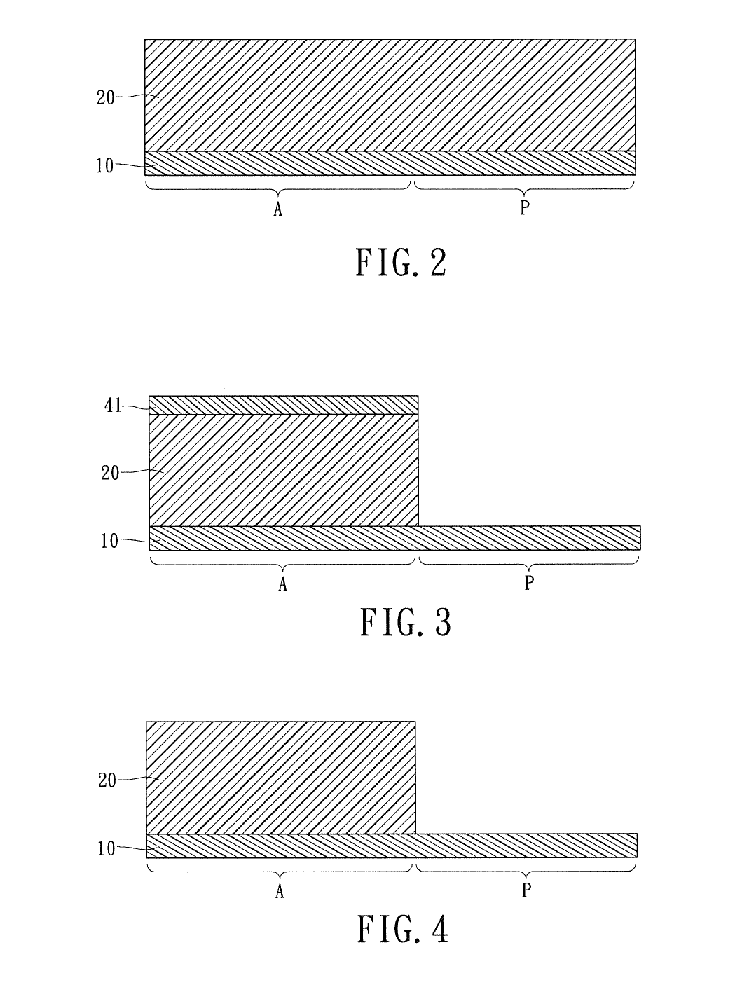

Forming a first oxidized layer 20 on the array region A. Specifically speaking, with reference to FIG. 2, the first oxidized layer 20 is deposited on the semiconductor substrate 10, where the first oxidized layer 20 is formed from the deposition of the borosilicate glass (BSG), phosphosilicate glass (PSG), and borophosphosilicate glass (BPSG). In other words, the first oxidized layer 20 is made of three sub-layers where the deposition sequence is not limited. Based on application requirement and the actual need, the oxidized layer 20 can also be formed by depositing at least one of the aforementioned materials without restriction. In other words, the first oxidized layer 20 may be made of BSG, PSG, BPSG, or a combination thereof.

Please refer to FIG. 3, a first photoresistance layer 41 is formed through the lithography process to cover on the first oxidized layer 20 of the array region A. Then, the first oxidized layer 20 deposited on the peripheral region P is removed by the means of dry etching. Only the first photoresistance layer 41 and the first oxidized layer 20 on the array region A remain. Then, with reference to FIG. 4, the first photoresistance layer 41 is removed from the first oxidized layer 20 by the means of wet etching, where only the first oxidized layer 20 on the array region A remains.

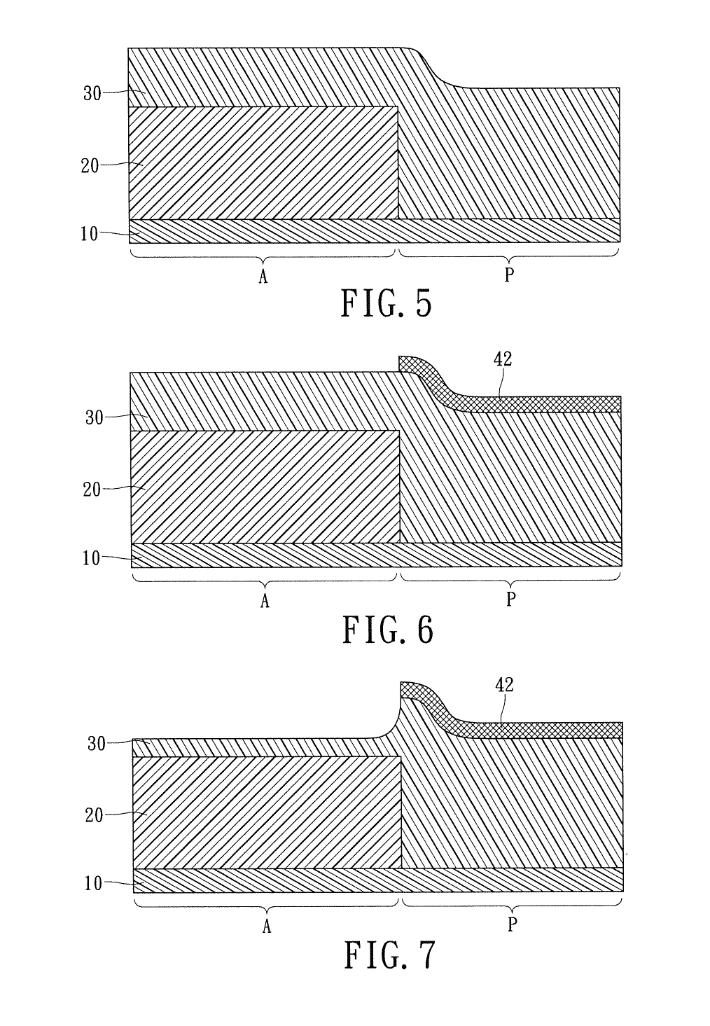

Please refer to FIG. 5, a second oxidized layer 30 is deposited on the first oxidized layer 20 and the peripheral region P. The second oxidized layer 30 is formed through the deposition of the plasma enhanced tetraethyl orthosilicate (TEOS), which is an undoped silicon glass (USG). Next, with reference to FIG. 6, a second photoresistance layer 42 is formed through the lithography process to cover on the second oxidized layer 30 of the peripheral region P. Then, with reference to FIG. 7, the second oxidized layer 30 is partially removed from the first oxidized layer 20 by means of dry etching. Thus, only the first oxidized layer 20 and a portion of the second oxidized layer 30 are left on the array region A. For the peripheral region P, the second photoresistance layer 42 and the second oxidized layer 30 remain. Then, the second photoresistance layer 42 is removed by means of wet etching, such that only the first and second oxidized layers 20 and 30 remain on the substrate 10.

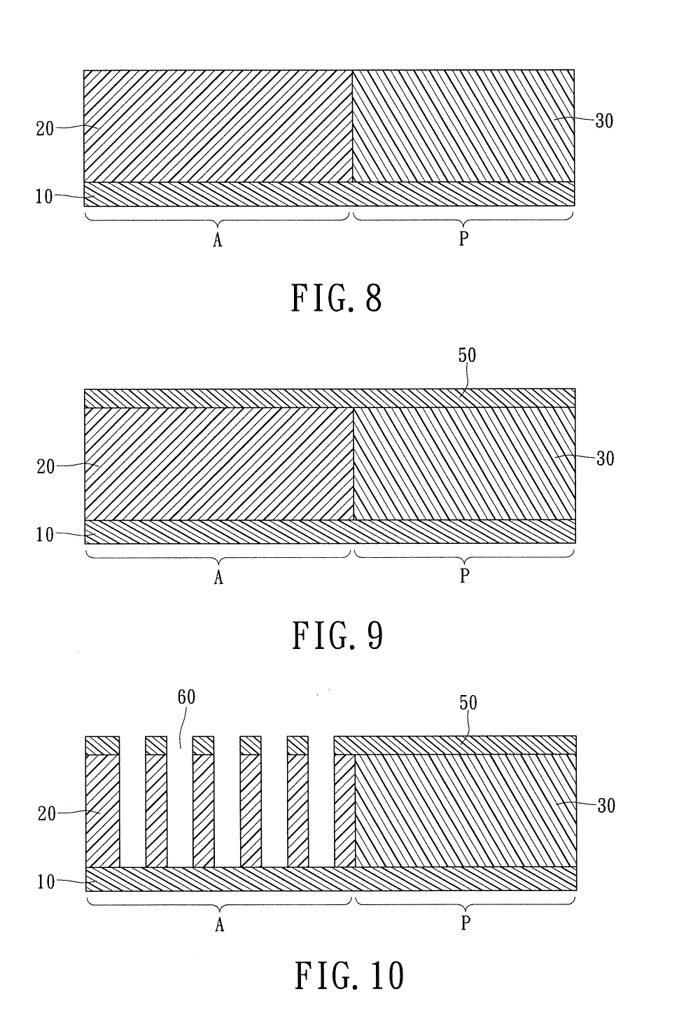

Please refer to FIG. 8, a planarizing process is performed on the first and the second oxidized layers 20 and 30, where the planarizing process is performed by means of chemical mechanical polishing to achieve a flat surface on the first and the second oxidized layers 20 and 30.

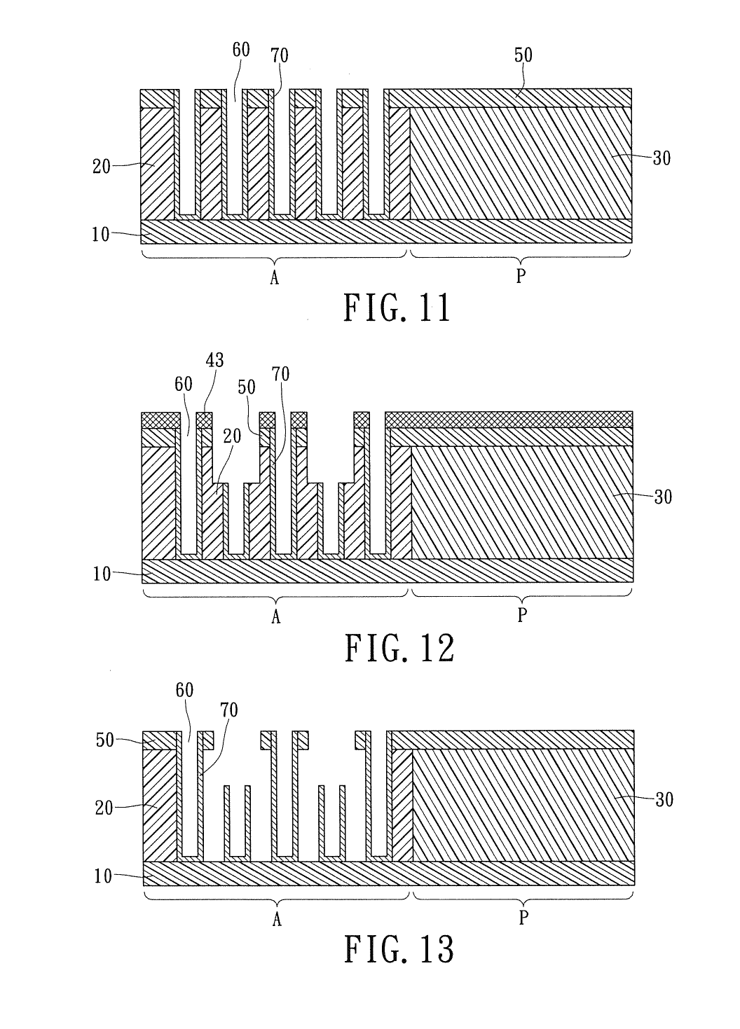

Please refer to FIG. 9, an insulating layer 50 is formed on the surface of the first and the second oxidized layers 20 and 30, where the insulating layer 50 is formed by the deposition of the silicon nitride. Next, with reference to FIG. 10, a plurality of trenches 60 is formed on the array region A. The trenches 60 is defined by at least one side surface and a base surface, and the trenches 60 pass through the insulating layer 50 and the first oxidized layer 20. For the method of forming the trenches 60, the lithography process is performed to define the location of the trenches 60, before the trenches 60 are formed on the insulating layer 50 and the first oxidized layer 20 by means of etching for the array region A. Next, with reference to FIG. 11, a conductive layer 70 is formed on the side and base surfaces of each of the trenches 60, where the conductive layer 70 is a titanium nitride layer. The conductive layer 70 is acts as the electrode of the DRAM capacitor, and the conductive layer 70 can be formed through the atomic layer deposition (ALD). It is worth noting that the ALD is suitable for forming membranes having a high depth-width ratio. Therefore, the formed conductive layer 70 has excellent uniformity and covering capability.

Please refer to FIG. 12, a portion of the conductive layer 70 and a portion of the conductive layer 50 are removed to form a plurality of notches for exposing the first oxidized layer 20. Specifically speaking, a patterned photoresistance layer 43 is formed to partially remove the conductive layer 70 and the insulating layer 50, where the patterned photoresistance layer 43 partially covers the conductive layer 70 and partially covers the insulating layer 50 before the uncovered portions of the conductive layer 70 and the insulating layer 50 are removed by means of dry etching. Nevertheless, a portion of the first oxidized layer 20 will be removed during the process of etching. Last of all, with reference to FIG. 13, the exposed first oxidized layer 20 and the remaining photoresistance layer 43 are removed by means of wet etching.

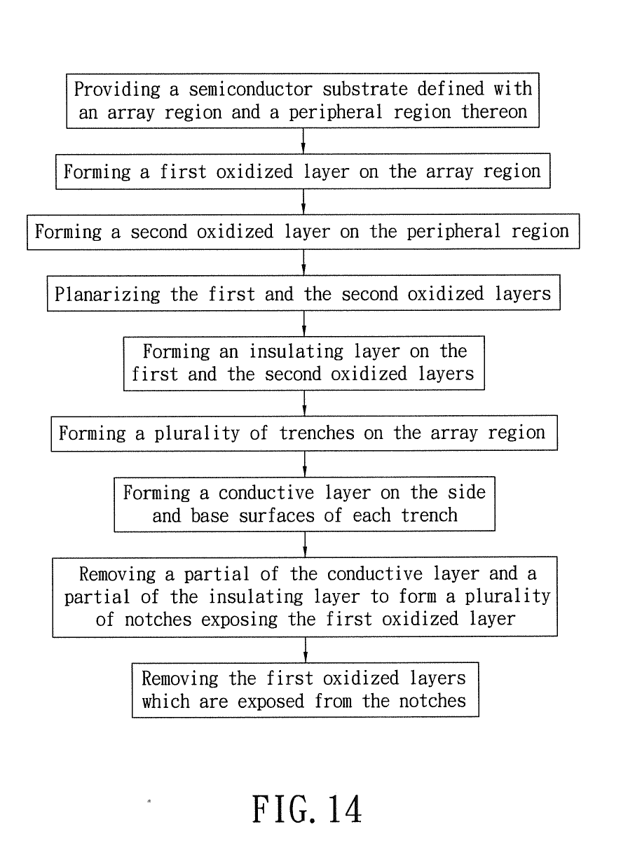

Please refer to FIG. 14, which shows a flow chart of the manufacturing method of the instant disclosure. By using the manufacturing method, a memory capacitor without a moat structure can be obtained.

Based on the above, the semiconductor structure formed from the manufacturing method of a memory capacitor without a moat structure provided in the instant disclosure does not have the moat structure. Therefore, the area for accommodating the capacitors is enlarged, allowing the semiconductor structure to hold more capacitors. Furthermore, the method provides an easier way of manufacturing the 4F2 DRAM.

The descriptions illustrated supra set forth simply the preferred embodiment of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A manufacturing method of a memory capacitor without a moat structure is provided, comprising the steps of:
providing a semiconductor substrate defined with an array region and a peripheral region;
forming a first oxidized layer on the array region;
forming a second oxidized layer on the peripheral region;
planarizing the first and the second oxidized layers;
forming an insulating layer on the first and the second oxidized layers;
forming a plurality of trenches on the array region, where each of the trenches is defined by at least one side surface and a base surface, and where the trenches pass through the first oxidized layer and the insulating layer formed on the first oxidized layer;
forming a conductive layer on the side and base surfaces of each trench;
removing a portion of the conductive layer and a portion of the insulating layer to form a plurality of notches for exposing the first oxidized layer; and
removing the first oxidized layers exposed from the notches.

2. The manufacturing method of a memory capacitor without a moat structure according to claim 1, wherein the step of forming the first oxidized layer on the array region further comprises the following steps of:
forming the first oxidized layer on the semiconductor substrate;
covering the first oxidized layer of the array region by a first photoresistance layer; and
removing the first oxidized layer from the peripheral region.

3. The manufacturing method of a memory capacitor without a moat structure according to claim 1, wherein the first oxidized layer is formed of BSG, PSG, and BPSG.

4. The manufacturing method of a memory capacitor without a moat structure according to claim 1, wherein the step of forming the second oxidized layer on the peripheral region further comprises the steps of:
forming the second oxidized layer on the first oxidized layer and the peripheral region;
covering the second oxidized layer of the peripheral region by a second photoresistance layer; and
removing the second oxidized layer from the first oxidized layer.

5. The manufacturing method of a memory capacitor without a moat structure according to claim 1, wherein the second oxidized layer is made of the plasma enhanced TEOS.

6. The manufacturing method of a memory capacitor without a moat structure according to claim 1, wherein the planarizing process of the first and the second oxidized layers is performed by means of chemical mechanical polishing.

7. The manufacturing method of a memory capacitor without a moat structure according to claim 1, wherein for the formation of the trenches, the location of the trenches are defined through the lithography process before the trenches are formed by means of etching.

8. The manufacturing method of a memory capacitor without a moat structure according to claim 1, wherein the conductive layer is a titanium nitride layer.

9. The manufacturing method of the memory capacitor without a moat structure according to claim 1, wherein the step of partially removing the conductive layer and partially removing the insulating layer further comprises the steps of:
forming a patterned photoresistance layer to partially cover the insulating layer and partially cover the conductive layer; and
removing the insulating layer and the conductive layer which are not covered by the patterned photoresistance layer.

10. The manufacturing method of a memory capacitor without a moat structure according to claim 1, wherein etching is used during the step of removing the first oxidized layer exposed from the notches.
